(19) United States
(12) Patent Application Publication
(10) Pub. No.: US 2020/0006551 A1
(43) Pub. Date: Jan. 2, 2020

(54) LATERALLY DIFFUSED METAL OXIDE SEMICONDUCTOR TRANSISTOR AND A METHOD OF MANUFACTURE OF THE SAME

(71) Applicant: Cirrus Logic International Semiconductor Ltd., Edinburgh (GB)

(72) Inventors: Zhonghai SHI, Austin, TX (US); Scott WARRICK, Austin, TX (US)

(73) Assignee: Cirrus Logic International Semiconductor Ltd., Edinburgh (GB)

(21) Appl. No.: 16/451,733

(22) Filed: Jun. 25, 2019

Related U.S. Application Data
(60) Provisional application No. 62/690,720, filed on Jun. 27, 2018.

(51) Int. Cl. H01L 29/78; H01L 29/66; H01L 29/10

(52) U.S. Cl. CPC H01L 29/7816; H01L 29/1095; H01L 29/66681

(57) ABSTRACT

Embodiments described herein relate to a method of manufacture of an LDMOS transistor an LDMOS transistor, and an integrated circuit comprising an LDMOS transistor. The method of manufacture of the LDMOS device comprises implanting a Fluorine dopant in a drift region of the LDMOS device in order to improve alignment between the drift region of the LDMOS transistor and a thicker area of a single gate oxide layer grown on the drift region and a channel region of the LDMOS transistor.

### TECHNICAL FIELD

Embodiments described herein relate to a method of manufacture of an LDMOS transistor, and an integrated circuit comprising an LDMOS transistor. The embodiments described herein in particular improve alignment between a drift region of the LDMOS transistor and a thicker area of an oxide layer grown on the drift region than the channel region of the LDMOS transistor.

### BACKGROUND

Laterally diffused metal oxide semiconductor (LDMOS) transistors may be used in product design where high voltage applications are desired. These LDMOS transistors may be fabricated on p/p+ silicon epitaxial layers or on a semiconductor substrate. The fabrication of LDMOS devices mostly involves various ion-implantation and subsequent annealing cycles. As an example, a drift region of this power metal-oxide-semiconductor field-effect transistor (MOSFET) may be fabricated using up to three ion implantation sequences in order to achieve the appropriate doping profile needed to withstand high electric fields.

FIG. 1 illustrates an example of an LDMOS transistor 100.

In the example illustrated in FIG. 1, the LDMOS transistor 100 is grown on a silicon substrate 101. The LDMOS transistor 100 comprises a source region 102 separated from an extended drain region 103 by a channel region 104. The dopant distribution in the channel region 104 may be formed by lateral diffusion of dopants from the source side of the channel region which forms a laterally graded channel region 104. The source region 102 and extended drain region 103 may be of the same conductivity type (e.g., n-type) while the channel region 103 is of the opposite conductivity type (e.g., p-type). It will be appreciated that the opposite conductivity types for the appropriate regions may also be used, for example the channel region may be n-type whilst the drain region 103 and source region are p-type.

A gate 105 actuates the LDMOS transistor 100. The gate 105 may be separated from the source region 102, channel region 104 and extended drain region 103 by a gate oxide layer 106.

LDMOS transistors are used in certain applications, for example an audio power amplifier which may form part of a codec, because of their advantageous linearity, power gain and breakdown voltage characteristics. The extended drain region 103 of an LDMOS transistor enables the transistor to withstand high breakdown voltages. The extended drain region 103 comprises an elongated drift region 107 which may extend one or more microns from a highly-doped drain contact region 108 to the channel region 103.

However, the LDMOS transistor 100 may suffer from Hot Carrier Injection. Hot Carrier Injection is a carrier that is injected from the conducting channel region in the silicon substrate into the gate dielectric. It may therefore be considered preferable to ensure that the gate oxide layer 106 is a thicker layer in order to reduce the effects of HCl.

However, a thinner gate oxide may enhance LDMOS performance, such as high drive current and lower on resistance,

However, a thin gate dielectric layer may lead to an increase in Time Dependent Dielectrics Breakdown (TDDB).

TDDB is a failure mechanism in MOSFETs, when the gate oxide breaks down as a result of the application of low electric field (as opposed to immediate breakdown, which is caused by strong electric field). The breakdown may be caused by the formation of a conducting path through the gate oxide layer 106 to the substrate 101 due to electron tunneling current. In this case. if the gate oxide layer is thicker, then the gate oxide layer may be more resilient to TDDB.

A thinner gate oxide over a channel region in an LDMOS transistor may enhance LDMOS performance, such as by allowing for a higher drive current and lower on resistance, but may degrade HCl and TDDB performance. However, a thicker gate oxide over the drift region of the LDMOS may compensate for some of the TDDB and HCl effects that may be caused by having a thinner gate oxide over the channel region.

FIGS. 2a to 2c illustrate an example of part of an LDMOS fabrication process.

In FIG. 2a, the Pwell 201 (which may also be referred to as the channel region 201) and Nwell 202 (which may also be referred to as the drift region 202) have been created (for example, using ion implantation and annealing processes as is known in the art). In this example, a gate oxide 203 has been formed over both the channel region 201 and the drift region 202. For example, the gate oxide 203 may have been formed using a thermal oxidation process.

A photoresist 204 has been applied to the gate oxide 203 intending to cover only the drift region 202. However, as this is a separate process, it is extremely difficult to line up the edge of the photoresist 204 with the edge of the drift region 202, and, in this example, the photoresist also covers part of the channel region 201.

In FIG. 2b, the gate oxide to the left of the photoresist 204 in FIG. 2a has been etched and replaced with a thinner gate oxide 205. The photoresist 204 has then been removed.

In FIG. 2c, a poly gate 206 is deposited over the gate oxide 203 and 205.

Further processes may then be completed to fabricate the full LDMOS device. These processes are known in the art.

The portion of the gate oxide 203 overlying the channel region 201 may result in degraded performance of the LDMOS transistor. In particular, this section of thicker gate oxide may result in a weaker device in terms of Saturation Drain Current, Linear Drain Current, Transconductance etc.

FIGS. 3a to 3c illustrate an example of part of the LDMOS fabrication process.

In FIG. 3a, similarly to as described in FIG. 2a, the Pwell 201 (which may also be referred to as a channel region 201) and Nwell 202 (which may also be referred to as the drift region 202) have been created (for example, using ion implantation and annealing processes as is known in the art). Again, in this example, a gate oxide 203 has been formed over both the channel region 201 and the drift region 202. For example, the gate oxide 203 may have been formed using a thermal oxidation process.

A photoresist 304 has been applied to the gate oxide 203 intending to cover only the drift region 202. However, as previously mentioned, as this is a separate process, it is extremely difficult to line up the edge of the photoresist 304 with the edge of the drift region 202, and, in this example, the photoresist does not fully overlay the drift region 202.

In FIG. 3b, the gate oxide to the left of the photoresist 304 in FIG. 3a has been etched and replaced with a thinner gate oxide 305. The photoresist 304 has been removed.

In FIG. 3c, a poly gate 206 is deposited over the gate oxide 203 and 305.

Further processes may then be completed to fabricate the full LDMOS device. These processes are known in the art.

The portion of the gate oxide 305 overlying the drift region 202 may result in degraded performance of the LDMOS transistor. For example, the thinner gate oxide 203 overlaying the drift region may result in an increase of the previously described TDDB and HCl effects.

It may therefore be desirable to better align a thicker portion of a gate oxide layer with the drift region 202, and similarly a thinner portion of the gate oxide layer with the channel region 201.

### SUMMARY

According to some embodiments there is provided a laterally diffused metal-oxide-semiconductor field-effect, LDMOS, transistor. The LDMOS transistor comprises: a substrate; a channel region formed within the substrate; a drift region formed within the substrate adjacent to the channel region, wherein the drift region comprises a Fluorine dopant; and a single gate oxide layer formed overlaying at least part of the channel region and at least part of the drift region, wherein a thicker portion of the single gate oxide layer overlays the at least part of drift region and a thinner portion of the single gate oxide layer overlays the at least part of channel region, and wherein a first junction between the thinner portion of the single gate oxide layer and the thicker portion of the single gate oxide layer is aligned with a second junction between the channel region and the drift region.

According to some embodiments, there is provided a method of manufacture of a laterally diffused metal-oxide-semiconductor field-effect, LDMOS, transistor. The method comprises: forming a channel region within a substrate; forming a drift region adjacent to the channel region, wherein the step of forming the drift region comprises implanting a Fluorine dopant in the drift region; and oxidising the channel region and drift region to generate a single gate oxide layer overlaying at least part of the channel region and at least part of the drift region, wherein a thicker portion of the single gate oxide layer overlays the at least part of drift region and a thinner portion of the single gate oxide layer overlays the at least part of the channel region, and wherein a first junction between the thinner portion of the single gate oxide layer and the thicker portion of the single gate oxide layer is aligned with a second junction between the channel region and the drift region.

According to some embodiments, there is provided an integrated circuit. The integrated circuit comprises a laterally diffused metal-oxide-semiconductor field-effect, LDMOS, transistor comprising: a substrate; a channel region formed within the substrate; a drift region formed within the substrate adjacent to the channel region, wherein the drift region comprises a Fluorine dopant; and a single gate oxide layer formed overlaying at least part of the channel region and at least part of the drift region, wherein a thicker portion of the single gate oxide layer overlays the at least part of drift region and a thinner portion of the single gate oxide layer overlays the at least part of channel region, and wherein a first junction between the thinner portion of the single gate oxide layer and the thicker portion of the single gate oxide layer is aligned with a second junction between the channel region and the drift region.

### BRIEF DESCRIPTION OF THE DRAWINGS

For a better understanding of the embodiments, and to show how they may be put into effect, reference will now be made, by way of example only, to the accompanying drawings, in which:

FIG. 1 illustrates an example of a laterally diffused metal oxide semiconductor, LDMOS, transistor in accordance with the prior art;

FIGS. 2a to 2c illustrate an example of part of the LDMOS fabrication process in accordance with the prior art;

FIGS. 3a to 3c illustrate an example of part of the LDMOS fabrication process in accordance with the prior art;

FIG. 4 illustrates a method of manufacture of an LDMOS transistor in accordance with some embodiments;

FIG. 5 illustrates step 402 of FIG. 4 in more detail in accordance with some embodiments;

FIG. 6 illustrates step 403 of FIG. 4 in more detail in accordance with some embodiments;

FIG. 7 illustrates an LDMOS according in accordance with some embodiments.

### DESCRIPTION

Example Embodiments of the Present Disclosure: The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

Some of the embodiments contemplated herein will now be described more fully with reference to the accompanying drawings. Other embodiments, however, are contained within the scope of the subject matter disclosed herein, the disclosed subject matter should not be construed as limited to only the embodiments set forth herein; rather, these embodiments are provided by way of example to convey the scope of the subject matter to those skilled in the art.

In order to address the aforementioned problems (HCl, TDDB and RTN), it may be considered useful to vary the thickness of the gate oxide across the channel region and the drift region of the LDMOS transistor.

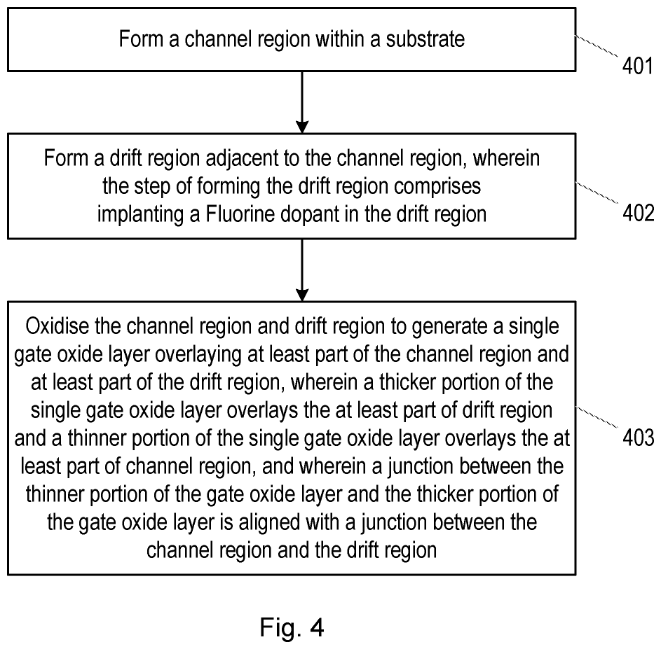

FIG. 4 illustrates a method of manufacture of an LDMOS transistor according to some embodiments.

In step 401, the method comprises forming a channel region within a substrate. It will be appreciated that this step 401 may be performed using ion implantation and annealing stages.

In step 402, the method comprises forming a drift region adjacent to the channel region, wherein the step of forming the drift region comprises implanting a Fluorine dopant in the drift region.

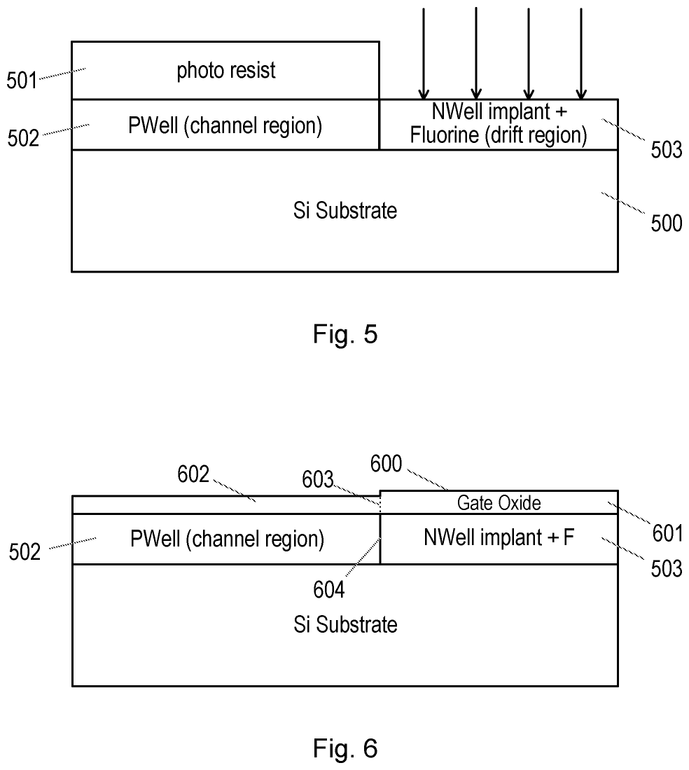

Step 402 is illustrated in more detail in FIG. 5.

A photoresist 501 may be utilised to cover the channel region 502 during step 402. In step 402, the drift region 503 is formed for example, the silicon forming the substrate 500 may be doped using Arsenic or Phosphorous to generate an Nwell as the drift region 503. The implantation dose of the Arsenic or Phosphorous may be in the range 1 e¹³ atoms per cm² to 2 e¹⁴ atoms per cm².

During the same stage, where the photoresist 501 is in place as illustrated in FIG. 5, the drift region 503 may also be doped with Fluorine. The implantation dose of Fluorine may be in the range 1 e¹³ atoms per cm² to 2 e¹⁴ atoms per cm².

It will be appreciated that different masks or photoresists may be utilised to create the appropriate channel region 502 and drift region 503 for an LDMOS device. However, during the stage to create the drift region, whatever mask or photoresist is in place to define the physical region of the silicon substrate 500 that will become the drift region 503, may also be used to dope the same physical region with Fluorine. In this way, the same region of the silicon substrate 500 will be both the drift region 503 and doped with Fluorine.

It will also be appreciated that the order of steps 401 and 402 may be reversed, and the drift region 503 may be formed from the silicon substrate 500 before the channel region 502.

The presence of Fluorine in the drift region 503 may also reduce Random Telegraph Noise (RTN). This may be attributed to for example, any one of: a reduction in interface-state density, an improvement in surface mobility, an increase in immunity to hot-carrier degradation and a reduction in a negative-bias instability and plasma-charging induced shifts.

In the above description the term “within” is used to describe how the channel region 502 and drift region 503 are formed from the silicon substrate 500. However, it will be appreciated that following the creation of the channel region 502 and the drift region 503, the resulting doped regions (e.g. the channel region 502 and the drift region 503) effectively lie on top of the remaining silicon substrate. It will be appreciated that the term “within” is to be understood to encompass the resultant structure in which the channel region 502 and the drift region 503 lie on top of the remaining silicon substrate.

In step 403, the method comprises oxidising the channel region and drift region to generate a single gate oxide layer overlaying at least part of the channel region and at least part of the drift region.

Step 403 is illustrated in more detail in FIG. 6.

In FIG. 6, the photoresist 501 is removed and the oxidising is performed resulting in the single gate oxide layer 600.

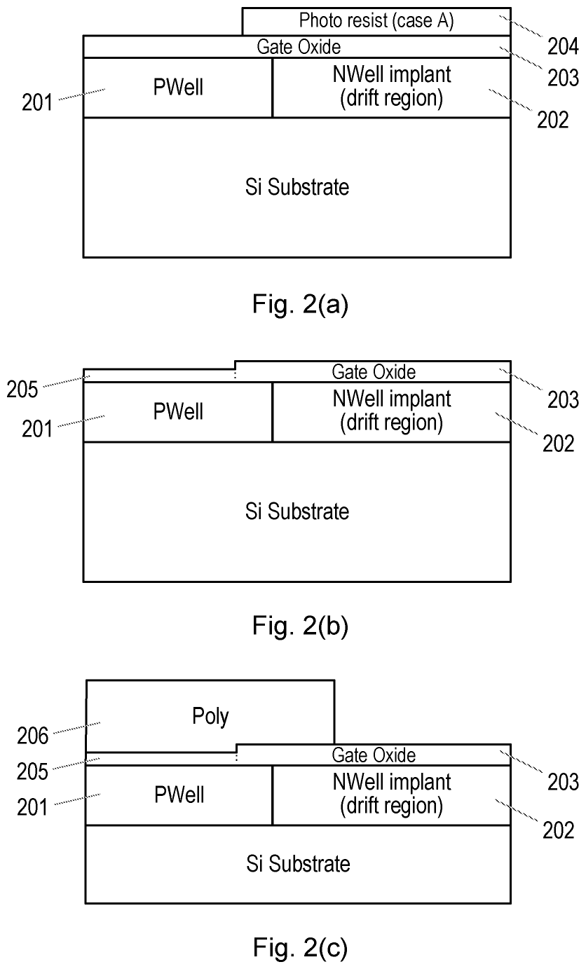

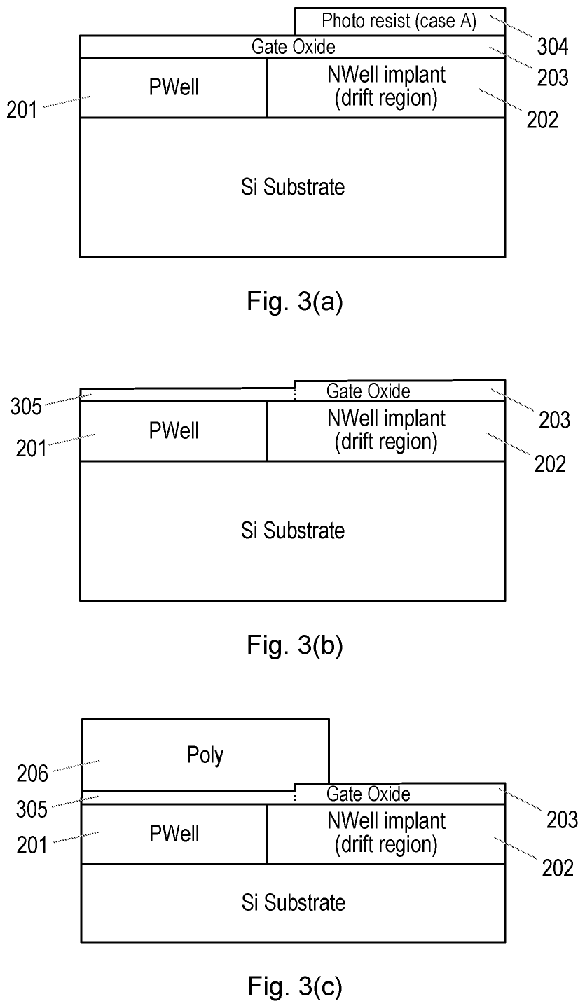

The presence of the Fluorine dopant in the drift region increases the rate of oxidation of the silicon, and during a single oxidation time period, the single gate oxide layer 600 is grown with a thicker portion 601 overlaying the drift region 503. A thinner portion 602 of the single gate oxide layer 600 overlays the channel region 502 where no fluorine dopant may be present. The single gate oxide layer 600 is referred to here as a single layer to represent that it is created during a single oxidation process, as opposed to the examples illustrated in FIGS. 2 and 3 in which the oxide layers of different thicknesses are created in two separated oxidation stages.

It will be appreciated that, in some examples, the single gate oxide layer 600 may not overlay the entire channel region 502 or the entire drift region 503.

It can therefore be seen from FIG. 6 that the thicker portion 601 of the single gate oxide layer 600 overlays at least part of drift region 503 and a thinner portion 602 of the single gate oxide layer 600 overlays at least part of channel region 502.

It can also be seen from FIG. 6 that a first junction 603 between the thinner portion 602 of the single gate oxide layer 600 and the thicker portion 601 of the single gate oxide layer 600 is aligned with a second junction 604 between the channel region 502 and the drift region 503. For example, the first junction 603 and the second junction 604 may be aligned as they meet at an interface between the drift and channel regions and the single gate oxide layer 600.

It will be appreciated that the shapes of the drift region 503 and the channel region 502 may result in a non-linear separation between the two regions through the depth of the substrate 500. The second junction 604 may therefore be defined by the point at the surface of the substrate below the single gate oxide layer 600 at which the channel region 502 and the drift region 503 meet.

Alternatively or additionally, the second junction 604 may be defined by the position at which the photoresist 501 or other mask met the surface of the substrate 500 during the creation of the drift region 503.

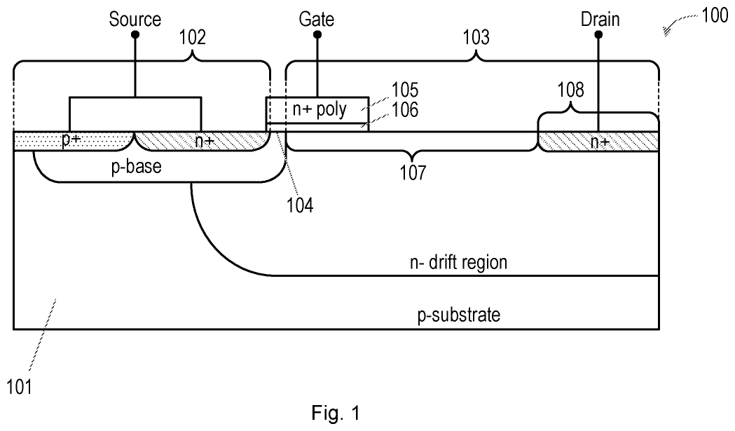

Further process steps may then be applied to the structure illustrated in FIG. 6 to create the remaining structures of an LDMOS transistor (for example as illustrated in FIG. 1), as will be known from the art.

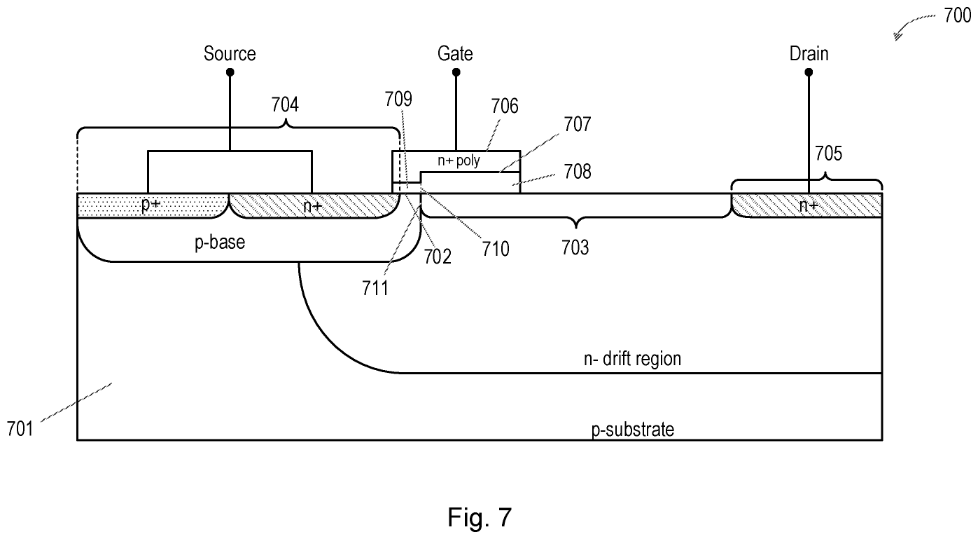

FIG. 7 illustrates an LDMOS transistor in accordance with some embodiments. The LDMOS transistor illustrated in FIG. 7 may be manufactured as described with reference to FIGS. 4 to 6.

Similarly to as described with reference to FIG. 1, the LDMOS transistor 700 comprises a substrate 701, a channel region 702 formed within the substrate 701; and a drift region 703 formed within the substrate adjacent to the channel region 702, wherein the drift region comprises a Fluorine dopant. The LDMOS 700 may also comprise other structures similar to those described in FIG. 1, for example, a source region 704, a drain region 705 and a gate 706.

As in FIG. 1, the gate 706 is separated from the source region 704, channel region 702 and drift region 703 by a gate oxide layer 707.

However, in this embodiment, the gate oxide layer 707 comprises a single gate oxide layer 707 formed overlaying at least part of the channel region 702 and at least part of the drift region 703, wherein a thicker portion 708 of the single gate oxide layer 707 overlays the at least part of drift region 703 and a thinner portion 709 of the single gate oxide layer 707 overlays the at least part of channel region 702.

A first junction 710 between the thinner portion 709 of the gate oxide layer 707 and the thicker portion 708 of the gate oxide layer 707 is aligned with a second junction 711 between the channel region 702 and the drift region 703.

As previously mentioned, it will be appreciated that the shapes of the drift region 703 and the channel region 702 may result in a non-linear separation between the two regions through the depth of the substrate 700. The second junction 711 may therefore be defined by the point at the surface of the substrate 701 below the single gate oxide layer 707 at which the channel region 702 and the drift region 703 meet.

Alternatively or additionally, the second junction 711 may be defined by the position at which a photoresist or other mask met the surface of the substrate 701 during the creation of the drift region 703.

The LDMOS transistor 700 may be used in amplifier circuitry (for example, power amplifiers) which may form part of an integrated circuit in, for example, a codec.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

It should be understood—especially by those having ordinary skill in the art with the benefit of this disclosure—that the various operations described herein, particularly in connection with the figures, may be implemented by other circuitry or other hardware components. The order in which each operation of a given method is performed may be changed, and various elements of the systems illustrated herein may be added, reordered, combined, omitted, modified, etc. It is intended that this disclosure embrace all such modifications and changes and, accordingly, the above description should be regarded in an illustrative rather than a restrictive sense.

Similarly, although this disclosure makes reference to specific embodiments, certain modifications and changes can be made to those embodiments without departing from the scope and coverage of this disclosure. Moreover, any benefits, advantages, or solutions to problems that are described herein with regard to specific embodiments are not intended to be construed as a critical, required, or essential feature or element.

Further embodiments likewise, with the benefit of this disclosure, will be apparent to those having ordinary skill in the art, and such embodiments should be deemed as being encompassed herein.

1. A laterally diffused metal-oxide-semiconductor field-effect (LDMOS) transistor comprising:
a substrate;
a channel region formed within the substrate;
a drift region formed within the substrate adjacent to the channel region, wherein the drift region comprises a Fluorine dopant; and
a single gate oxide layer formed overlaying at least part of the channel region and at least part of the drift region, wherein a thicker portion of the single gate oxide layer overlays the at least part of drift region and a thinner portion of the single gate oxide layer overlays the at least part of channel region, and wherein a first junction between the thinner portion of the single gate oxide layer and the thicker portion of the single gate oxide layer is aligned with a second junction between the channel region and the drift region.

2. The LDMOS transistor of claim 1 wherein the channel region comprises a p-well.

3. The LDMOS transistor of claim 1 wherein the drift region comprise an n-well.

4. The LDMOS transistor of claim 1 wherein the oxide layer comprises silicon dioxide.

5. The LDMOS transistor of claim 1 wherein the drift region comprises Fluorine having an implantation dose in the range 1 e¹³ atoms per cm² to 2 e¹⁴ atoms per cm².

6. The LDMOS transistor of claim 1 wherein the drift region further comprises a Phosphorus dopant or an Arsenic dopant.

7. A method of manufacture of a laterally diffused metal-oxide-semiconductor field-effect (LDMOS) transistor, the method comprising:
forming a channel region within a substrate;
forming a drift region adjacent to the channel region, wherein the step of forming the drift region comprises implanting a Fluorine dopant in the drift region; and
oxidising the channel region and drift region to generate a single gate oxide layer overlaying at least part of the channel region and at least part of the drift region, wherein a thicker portion of the single gate oxide layer overlays the at least part of drift region and a thinner portion of the single gate oxide layer overlays the at least part of channel region, and wherein a first junction between the thinner portion of the single gate oxide layer and the thicker portion of the single gate oxide layer is aligned with a second junction between the channel region and the drift region.

8. The method of claim 7 wherein the step of implanting comprises implanting the Fluorine dopant with an implantation dose in the range 1 e¹³ atoms per cm² to 2 e¹⁴ atoms per cm².

9. The method of claim 7 wherein the channel region comprises a p-well.

10. The method of claim 7 wherein the drift region comprise an n-well.

11. The method of claim 7 wherein the oxide layer comprises silicon dioxide.

12. The method of claim 7 wherein the drift region further comprises a Phosphorus dopant or an Arsenic dopant.

13. An integrated circuit comprising a laterally diffused metal-oxide-semiconductor field-effect, LDMOS, transistor comprising:
a substrate;
a channel region formed within the substrate;
a drift region formed within the substrate adjacent to the channel region, wherein the drift region comprises a Fluorine dopant; and
a single gate oxide layer formed overlaying at least part of the channel region and at least part of the drift region, wherein a thicker portion of the single gate oxide layer overlays the at least part of drift region and a thinner portion of the single gate oxide layer overlays the at least part of channel region, and wherein a first junction between the thinner portion of the single gate oxide layer and the thicker portion of the single gate oxide layer is aligned with a second junction between the channel region and the drift region.

14. The integrated circuit of claim 13 wherein the channel region comprises a p-well.

15. The integrated circuit of claim 13 wherein the drift region comprise an n-well.

16. The integrated circuit of claim 13 wherein the oxide layer comprises silicon dioxide.

17. The integrated circuit of claim 13 wherein the drift region comprises Fluorine having an implantation dose in the range 1 e¹³ atoms per cm² to 2 e¹⁴ atoms per cm².

18. The integrated circuit of claim 13 wherein the drift region further comprises a Phosphorus dopant or an Arsenic dopant.
